(19) United States
(12) Patent Application Publication
(10) Pub. No.: US 2012/0068051 A1
(43) Pub. Date: Mar. 22, 2012

(54) Method Of Driving An Image Sensor

(75) Inventors: Jung-chak Ahn, Yongin-si (KR); Yi-Tae Kim, Hwaseong-si (KR)

(73) Assignee: SAMSUNG ELECTRONICS CO., LTD., Suwon-si (KR)

(21) Appl. No.: 13/233,250

(22) Filed: Sep. 15, 2011

(30) Foreign Application Priority Data
Sep. 17, 2010 (KR) 10-2010-0091922

(51) Int. Cl. H01L 27/146

(52) U.S. Cl. 250/208.1

(57) ABSTRACT

In a method of driving an image sensor, incident light is converted into electric charges in a photoelectric conversion region during a first operation mode. At least one of collected electric charges and overflowed electric charges is accumulated in a floating diffusion region based on illuminance of the incident light. The collected electric charges indicate electric charges that are collected in the photoelectric conversion region. The overflowed electric charges indicate electric charges that have overflowed from the photoelectric conversion region.

### CROSS-REFERENCE TO RELATED APPLICATION

This application claims priority under 35 USC §119 to Korean Patent Application No. 2010-0091922, filed on Sep. 17, 2010 in the Korean Intellectual Property Office (KIPO), the entire contents of which are incorporated herein by reference.

### BACKGROUND

1. Technical Field

Example embodiments relate to an image sensor, and more particularly to a method of driving an image sensor.

2. Description of the Related Art

An image sensor receives incident light, converts the incident light into electric charges, and outputs an electric signal corresponding to the electric charges. A dynamic range (DR) of the image sensor represents the capability of the image sensor to distinguish various levels of brightness for a pixel between maximum brightness and minimum brightness. The dynamic range of the image sensor may be extended by decreasing a noise level of the image sensor or by increasing a saturation level (i.e., a maximum level) of a signal recognizable by the image sensor.

### SUMMARY

Some example embodiments provide a method of driving an image sensor capable of having a wide dynamic range and improved performances.

In a method of driving an image sensor according to some example embodiments, an incident light is converted into electric charges in a photoelectric conversion region during a first operation mode. At least one of collected electric charges and overflowed electric charges is accumulated in a floating diffusion region based on illuminance of the incident light. The collected electric charges indicate electric charges that are collected in the photoelectric conversion region. The overflowed electric charges indicate electric charges that have overflowed from the photoelectric conversion region.

The overflowed electric charges may be selectively accumulated in the floating diffusion region based on the illuminance of the incident light during the first operation mode. The collected electric charges may be accumulated in the floating diffusion region during a second operation mode after the first operation mode.

The floating diffusion region may be reset during a first period of the first operation mode. The overflowed electric charges may be accumulated in the floating diffusion region during a second period of the first operation mode when the illuminance of the incident light is higher than a reference illuminance. The reset state of the floating diffusion region may be maintained during the second period of the first operation mode when the illuminance of the incident light is lower than the reference illuminance.

The image sensor may include a reset gate that resets the floating diffusion region in response to a reset signal. The reset signal may be activated during the first period of the first operation mode and may be deactivated during the second period of the first operation mode.

A dynamic range of the image sensor may be controlled by changing a start time point of the first period of the first operation mode.

The floating diffusion region may be reset during a first period of the second operation mode. The collected electric charges may be accumulated in the floating diffusion region during a second period of the second operation mode.

The image sensor may include a reset gate that resets the floating diffusion region in response to a reset signal, and a transfer gate that transfers the collected electric charges from the photoelectric conversion region to the floating diffusion region based on a transfer signal. The reset signal may be activated during the first period of the second operation mode, and the transfer signal may be activated during the second period of the second operation mode.

In at least one example embodiment, an image signal corresponding to the illuminance of the incident light may be provided during a second operation mode after the first operation mode.

A first output signal may be generated by sampling an electric potential of the floating diffusion region during a first sampling period of the second operation mode. A reference signal may be generated by sampling the electric potential of a reset state of the floating diffusion region during a second sampling period of the second operation mode. A second output signal may be generated by sampling the electric potential of the floating diffusion region during a third sampling period of the second operation mode. The image signal may be generated based on the reference signal, the first output signal and the second output signal.

The first output signal may correspond to the overflowed electric charges when the illuminance of the incident light is higher than a reference illuminance, and may correspond to the electric potential of the reset state of the floating diffusion region when the illuminance of the incident light is lower than the reference illuminance. The second output signal may correspond to the collected electric charges.

A first sampling signal may be generated by performing correlated double sampling on the reference signal and the first output signal. A second sampling signal may be generated by performing the correlated double sampling on the reference signal and the second output signal. The image signal may be generated by adding the first sampling signal to the second sampling signal.

The image sensor may include a single line buffer storing the first sampling signal.

The image sensor may include an overflow gate that transfers the overflowed electric charges from the photoelectric conversion region to the floating diffusion region. A charge storage capacity of the photoelectric conversion region may be controlled by adjusting a voltage level of the overflow signal applied to the overflow gate.

The floating diffusion region may have a structure for reducing a leakage current.

The photoelectric conversion region and the floating diffusion region may be for rued in a semiconductor substrate. The floating diffusion region may include a first impurity region, a second impurity region and a third impurity region. The first impurity region may be formed at a surface portion of the semiconductor substrate. The second impurity region may be formed at the surface portion of the semiconductor substrate and adjacent to the first impurity region. The second impurity region may be partially overlapped with the first impurity region. The third impurity region may be formed adjacent to the first impurity region and the second impurity region. The first impurity region may be surrounded by the third impurity region.

According to at least one example embodiment, a method of operating an image sensor may include converting incident light into electric charges in a photoelectric conversion region during an integration operation; and collecting overflow charges, the overflow charges being electric charges which exceed a charge storage capacity of the photoelectric conversion region in a floating diffusion region during the integration operation, if the a level of the incident light exceeds a reference level.

A dynamic range of the image sensor may be controlled by selectively adjusting a timing of a reset operation, the reset operation resetting the floating diffusion region before collecting the overflow charges.

According to at least one example embodiment, a method of operating an image sensor may include generating a first output signal during a read out operation based on overflow charges collected by a floating diffusion region, the overflow charges being charges which exceeded a charge storage capacity of a photoelectric conversion region during an integration operation; generating a reference signal during the read out operation, the reference signal representing a voltage level of the floating diffusion region in a reset state; generating a second output signal during the read out operation based on charges transferred from the photoelectric conversion region to the floating diffusion region during the read out operation; and generating an image signal based on the first output signal, the second output signal, and the reference signal.

The method may further comprise performing a first reset operation resetting the floating diffusion region before generating the first signal; and performing a second reset operation resetting the floating diffusion region after generating the first signal and before generating the reference signal.

The generating the image signal may include generating a first sampling signal based on the first output signal and the reference signal; generating a second sampling signal based on the second output signal and the reference signal; and generating the image signal based on the first and second sampling signals.

Accordingly, in a method of driving an image sensor according to at least one example embodiment, the photoelectric conversion region is relatively lightly doped with impurities, and the overflowed electric charges are selectively accumulated in the floating diffusion region based on the illuminance of the incident light for providing the image signal. Thus, the image sensor operated by the method according to at least one example embodiment may have an improved dark level performance, a reduced image lag phenomenon and a wide dynamic range, thereby having improved performances.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a flow chart illustrating a method of driving an image sensor according to some example embodiments.

FIG. 2 is a block diagram illustrating a CMOS image sensor for describing the method of driving the image sensor according to some example embodiments.

FIG. 3 is a circuit diagram illustrating an example of a unit pixel included in the CMOS image sensor of FIG. 2.

FIG. 4 is a plan view of an example of the unit pixel included in the CMOS image sensor of FIG. 2.

FIG. 5 is a cross-sectional view of an example of the unit pixel taken along a line I-I′ of FIG. 4.

FIGS. 6, 7, 8 and 9 are diagrams for describing operations of the unit pixel of FIG. 5 operated by the method of FIG. 1.

FIG. 10 is a flow chart illustrating an example of accumulating at least one of the collected electric charges and the overflowed electric charges of FIG. 1.

FIG. 11 is a flow chart illustrating an example of selectively accumulating the overflowed electric charges of FIG. 10.

FIG. 12 is a flow chart illustrating an example of accumulating the collected electric charges of FIG. 10.

FIG. 13 is a flow chart illustrating a method of driving an image sensor according to other example embodiments.

FIG. 14 is a flow chart illustrating an example of providing the image signal of FIG. 13.

FIG. 15 is a flow chart illustrating an example of generating the image signal of FIG. 14.

FIG. 16 is a timing diagram for describing the method of driving the image sensor according to some example embodiments.

FIGS. 17, 18 and 19 are diagrams for describing the method of driving the image sensor according to some example embodiments.

FIG. 20 is an enlarged view of a portion “A” in FIG. 5.

FIG. 21 is a circuit diagram illustrating another example of the unit pixel included in the CMOS image sensor of FIG. 2.

FIG. 22 is a diagram for describing an operation of the unit pixel of FIG. 21 operated by the method of FIG. 1.

FIG. 23 is a block diagram illustrating an electronic system having an image sensor according to some example embodiments.

### DETAILED DESCRIPTION OF THE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular fauns disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

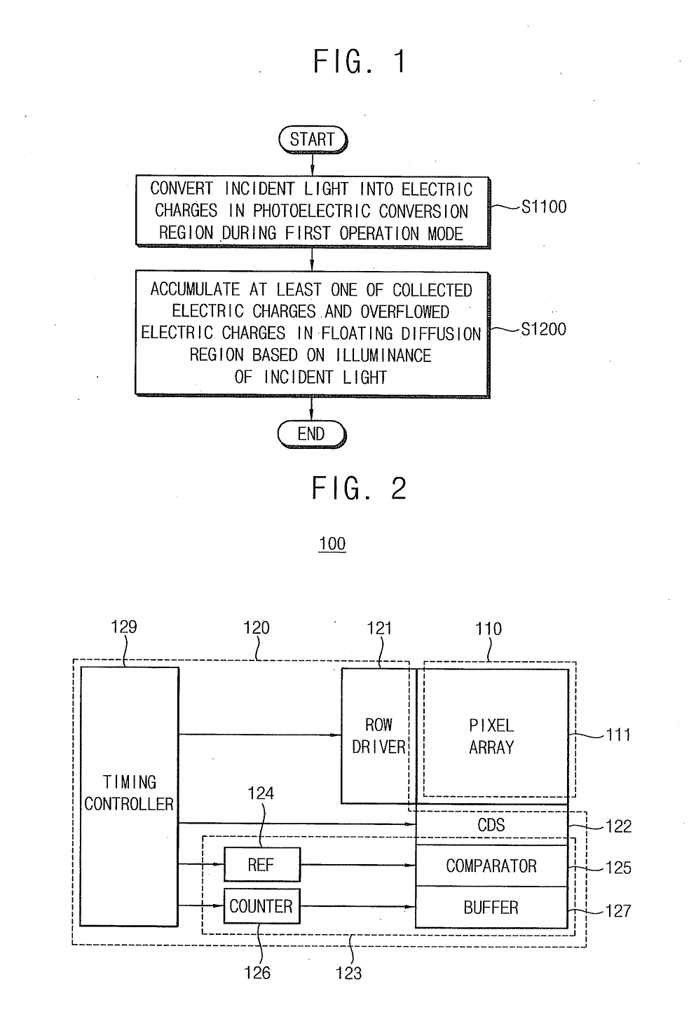

FIG. 1 is a flow chart illustrating a method of driving an image sensor according to some example embodiments.

The method illustrated in FIG. 1 may be applied to drive an image sensor including unit pixels where transfer gates are formed between photoelectric conversion regions (e.g., photodiodes) and floating diffusion regions. Hereinafter, the method of driving the image sensor according to some example embodiments will be described based on a complementary metal-oxide semiconductor (CMOS) image sensor. However, the method of driving the image sensor according to some example embodiments may be applied to drive a charge-coupled device (CCD) image sensor. Detailed configurations of a CMOS image sensor and a unit pixel will be described below with reference to FIGS. 2 through 9, 21 and 22.

The CMOS image sensor may operate alternatively in two modes, that is, a first operation mode and a second operation mode. The first operation mode may be referred to as an integration mode and the second operation mode may be referred to as a readout mode. The CMOS image sensor may perform different operations depending on the operation modes. For example, during the first operation mode, image information on an object to be captured is obtained by collecting charge carriers (e.g., electron-hole pairs) in photoelectric conversion regions proportional to intensity of incident lights through an open shutter of the CMOS image sensor. During the second operation mode after the first operation mode, the shutter is closed, and the image information in a form of charge carriers is converted into electrical signals.

Referring to FIG. 1, in the method of driving the image sensor according to some example embodiments, an incident light is converted into electric charges in the photoelectric conversion region during the first operation mode (step S1100). At least one of collected electric charges and overflowed electric charges is accumulated in the floating diffusion region based on illuminance of the incident light (step S1200). The step S1200 will be described below with reference to FIGS. 10 through 12.

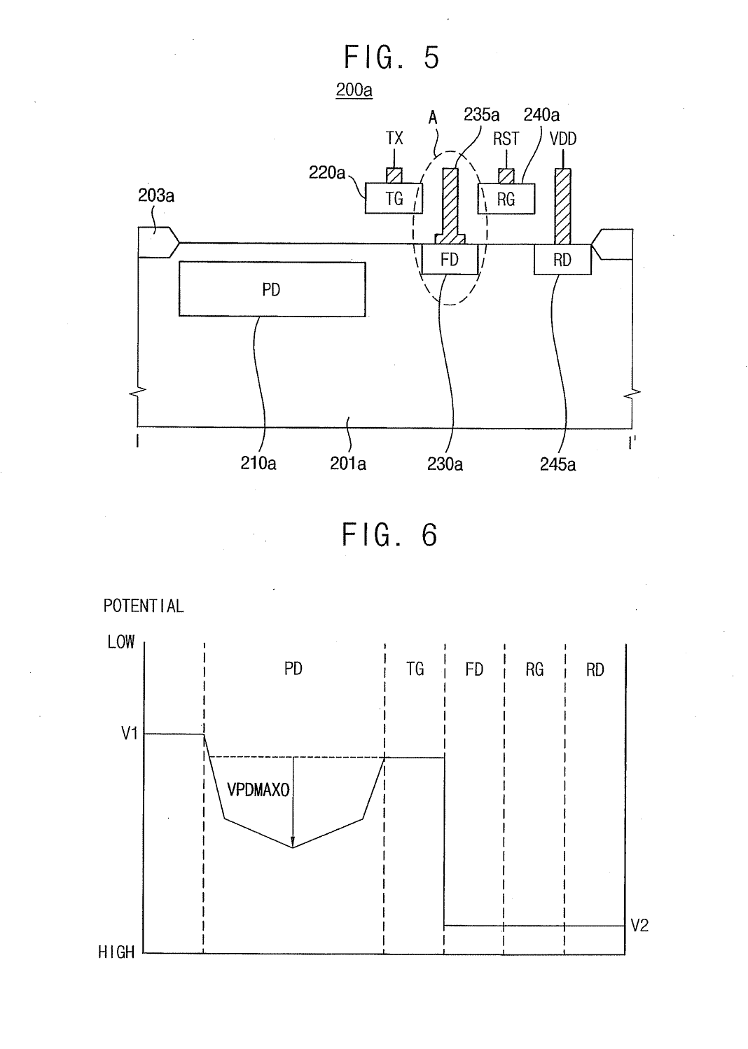

The photoelectric conversion region is lightly doped with impurities (e.g., n-type impurities). As described below with reference to FIGS. 5 through 9, the doping density of the photoelectric conversion region in the image sensor operated by the method of FIG. 1 may be lower than a doping density of a photoelectric conversion region in a conventional image sensor. The collected electric charges indicate electric charges that are generated in the photoelectric conversion region based on the incident light and are collected in the photoelectric conversion region. The overflowed electric charges indicate electric charges that are generated in the photoelectric conversion region based on the incident light and are overflowed from the photoelectric conversion region.

In the conventional image sensor, the photoelectric conversion regions are relatively heavily doped with impurities. Thus, the conventional photoelectric conversion regions have a relatively large charge storage capacity, and the conventional image sensor has an improved signal-to-noise ratio (SNR) performance. However, a dark level (i.e., black level) performance of the conventional image sensor may be degraded because a dark current increases due to the relatively large charge storage capacity. An image lag phenomenon may occur in the conventional image sensor due to electric charges that are not transferred to the floating diffusion region and remain in the photoelectric conversion region.

In the image sensor operated by the method according to some example embodiments, the photoelectric conversion regions are relatively lightly doped with impurities (e.g., n-type impurities). In the method of driving the image sensor according to some example embodiments, at least one of the collected electric charges and the overflowed electric charges are accumulated in the floating diffusion region for providing an electric image signal. The overflowed electric charges may be selectively accumulated in the floating diffusion region based on the illuminance of the incident light. Thus, the image sensor operated by the method according to some example embodiments may have improved performance. For example, the image sensor operated by the method according to some example embodiments may have an improved dark level performance and a wide dynamic range, and the image lag phenomenon may be reduced.

Hereinafter, the method of driving the image sensor according to some example embodiments will be explained in detail with reference to example configurations of the CMOS image sensor and the unit pixel.

FIG. 2 is a block diagram illustrating a CMOS image sensor for describing the method of driving the image sensor according to some example embodiments.

Referring to FIG. 2, the CMOS image sensor 100 includes a photoelectric conversion unit 110 and a signal processing unit 120.

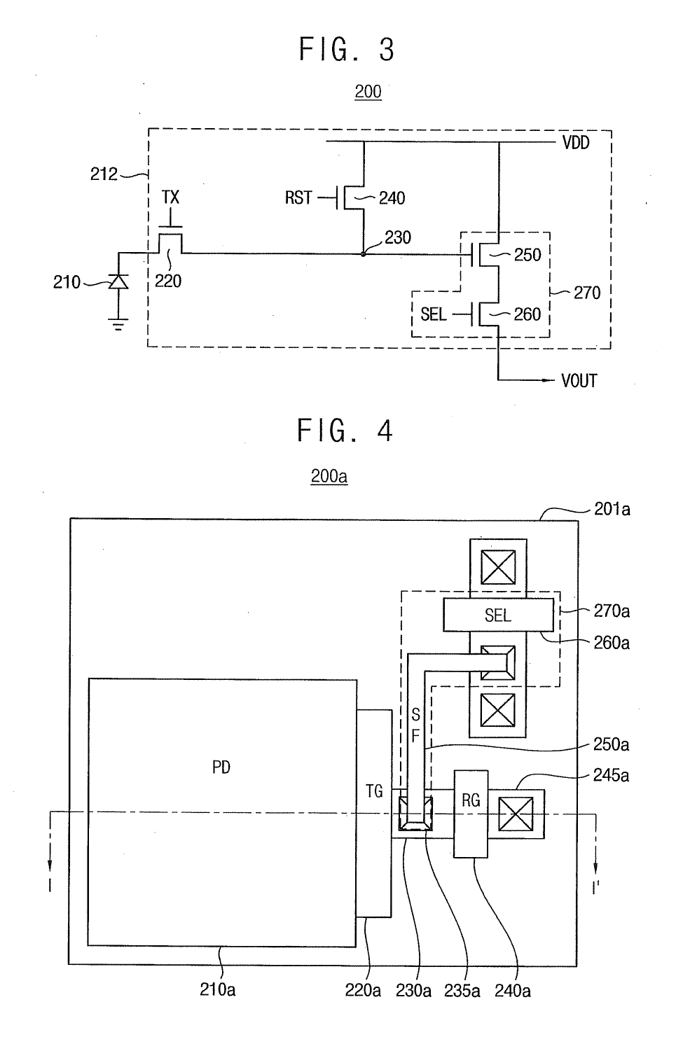

The photoelectric conversion unit 110 generates electrical signals based on the incident light. The photoelectric conversion unit 110 may include a pixel array 111 where unit pixels are arranged in a matrix form. Detailed configurations of the unit pixel will be described below with reference to FIGS. 3 through 5. The photoelectric conversion unit 110 may further include an infrared filter and/or a color filter.

The signal processing unit 120 may include a row driver 121, a correlated double sampling (CDS) unit 122, an analog-digital converting (ADC) unit 123 and a timing controller 129.

The row driver 121 is connected with each row of the pixel array 111. The row driver 121 may generate driving signals to drive each row. For example, the row driver 121 may drive a plurality of unit pixels included in the pixel array 111 row by row.

The CDS unit 122 performs a CDS operation by obtaining a difference between reset components and measured signal components using capacitors and switches, and outputs analog signals corresponding to effective signal components. The CDS unit 122 may include a plurality of CDS circuits that are connected to column lines, respectively. The CDS unit 122 may output the analog signals corresponding to the effective signal components column by column.

The ADC unit 123 converts the analog signals corresponding to the effective signal components into digital signals. The ADC unit 123 may include a reference signal generator 124, a comparison unit 125, a counter 126 and a buffer unit 127. The reference signal generator 124 may generate a reference signal (e.g., a ramp signal having a slope), and provide the reference signal to the comparison unit 125. The comparison unit 125 may compare the reference signal with the analog signals corresponding to the effective signal components, and output comparison signals having respective transition timings according to respective effective signal component column by column. The counter 126 may perform a counting operation to generate a counting signal, and provide the counting signal to the buffer unit 127. The buffer unit 127 may include a plurality of latch circuits (e.g., static random access memory (SRAM)) respectively connected to the column lines. The buffer unit 127 may latch the counting signal of each column line in response to the transition of each comparison signal, and output the latched counting signal as image data.

In at least one example embodiment, the ADC unit 123 may further include an adder circuit that adds the analog signals output from the CDS unit 122. The buffer unit 127 may include a plurality of single line buffers.

The timing controller 129 controls operation timings of the row driver 121, the CDS unit 122, and the ADC unit 123. The timing controller 129 may provide timing signals and control signals to the row driver 121, the CDS unit 122, and the ADC unit 123.

FIG. 3 is a circuit diagram illustrating an example of a unit pixel included in the CMOS image sensor of FIG. 2.

Referring to FIG. 3, the unit pixel 200 may include a photoelectric conversion element 210 and a signal generation unit 212.

The photoelectric conversion element 210 performs a photoelectric conversion operation. For example, the photoelectric conversion element 210 may convert the incident light into the electric charges during the first operation mode. The photoelectric conversion element 210 may include, for example, a photo diode, a photo transistor, a photo gate, a pinned photo diode (PPD), or a combination thereof.

The signal generation unit 212 generates an electric signal based on the electric charges generated by the photoelectric conversion operation. The unit pixel 200 may have various structures including, for example, one-transistor structure, three-transistor structure, four-transistor structure, five-transistor structure, structure where some transistors are shared by a plurality of unit pixels, etc. As illustrated in FIG. 3, the unit pixel 200 may have four-transistor structure. In this case, the signal generation unit 212 may include a transfer transistor 220, a reset transistor 240, a drive transistor 250, a select transistor 260 and a floating diffusion node 230. The floating diffusion node 230 may correspond to the floating diffusion region and may be connected to a capacitor (not illustrated).

The transfer transistor 220 may include a first electrode connected to the photoelectric conversion element 210, a second electrode connected to the floating diffusion node 230, and a gate electrode applied to a transfer signal TX. The reset transistor 240 may include a first electrode applied to a power supply voltage VDD, a second electrode connected to the floating diffusion node 230, and a gate electrode applied to a reset signal RST. The drive transistor 250 may include a first electrode applied to the power supply voltage VDD, a gate electrode connected to the floating diffusion node 230, and a second electrode. The select transistor 260 may include a first electrode connected to the second electrode of the drive transistor 250, a gate electrode applied to a select signal SEL, and a second electrode providing an output voltage VOUT. The drive transistor 250 and the select transistor 260 may be part of an output unit 270.

Although the unit pixel 200 having four-transistor structure is illustrated in FIG. 3 for convenience of illustration, the unit pixel included in the CMOS image sensor may have various structures that include the photoelectric conversion element and the floating diffusion node.

FIG. 4 is a plan view of an example of the unit pixel included in the CMOS image sensor of FIG. 2.

Referring to FIG. 4, the unit pixel 200a may include a photoelectric conversion region 210a, a transfer gate 220a, a floating diffusion region 230a, a reset gate 240a and an output unit 270a. The photoelectric conversion region 210a, the transfer gate 220a, the floating diffusion region 230a, the reset gate 240a and the output unit 270a may be formed in or over a semiconductor substrate 201a.

The photoelectric conversion region 210a is formed in the semiconductor substrate 201a. The collected electric charges may be generated in the photoelectric conversion region 210a by collecting electric charges (e.g., electrons) from electron-hole pairs generated by the incident light on the semiconductor substrate 201a. When the illuminance of the incident light is higher than a reference illuminance (i.e., a threshold illuminance), the number of the electric charges generated by the incident light may be larger than the number of electric charges corresponding to the charge storage capacity of the photoelectric conversion region 210a, and thus the overflow electric charges may be generated.

The transfer gate 220a is formed over the semiconductor substrate 201a. The transfer gate 220a may be disposed between the photoelectric conversion region 210a and the floating diffusion region 230a. The transfer gate 220a may transfer the electric charges collected by the photoelectric conversion region 210a to the floating diffusion region 230a in response to the transfer signal TX.

The floating diffusion region 230a is formed in the semiconductor substrate 201a. When some electric charges are overflowed from the photoelectric conversion region 210a due to the incident light having a relatively high illuminance, the overflow electric charges may be accumulated in the floating diffusion region 230a during the first operation mode. The collected electric charges may be accumulated in the photoelectric conversion region 210a during the second operation mode.

The reset gate 240a is formed over the semiconductor substrate 201a. The reset gate 240a may be disposed between the floating diffusion region 230a and a reset drain 245a receiving the power supply voltage VDD. The reset gate 240a may reset the floating diffusion region 230a in response to the reset signal RST. For example, after the reset operation, an electric potential level (i.e., a voltage level) of the floating diffusion region 230a may correspond to the level of the power supply voltage VDD.

The output unit 270a is formed over the semiconductor substrate 201a. The output unit 270a may output the electric signal corresponding to the electric charges accumulated in the floating diffusion region 230a. The output unit 170a may include a drive transistor 250a for amplifying the voltage of the floating diffusion region 230a, and a select transistor 260a for outputting the voltage amplified by the drive transistor 250a to the column line. The unit pixel 200a may further include a contact 235a for electrically connecting the floating diffusion region 230a and the output unit 270a.

FIG. 5 is a cross-sectional view of an example of the unit pixel taken along a line I-I′ of FIG. 4.

As described below with reference to FIGS. 7 through 9, when the illuminance of the incident light is higher than the reference illuminance, the overflowed electric charges may be transferred from the photoelectric conversion region 210a, via a charge transfer path (not illustrated) to the floating diffusion region 230a. The charge transfer path may be formed in the semiconductor substrate 201a between the photoelectric conversion region 210a and the floating diffusion region 230a. For example, when the photoelectric conversion region 210a and the floating diffusion region 230a are formed in the semiconductor substrate 201a by ion implantation process, the charge transfer path may be formed in the bulk of the semiconductor substrate 201a by adjusting an incident angle of an ion beam and a level of an ion energy.

Referring to FIG. 5, the semiconductor substrate 201a may include a bulk substrate (not illustrated) and an epitaxial layer (not illustrated) formed over the bulk substrate. For example, the epitaxial layer may be doped with p-type impurities such that doping density of the epitaxial layer may gradually decrease in a direction to a surface where gates 220a and 240a are overlain.

The photoelectric conversion region 210a may be formed in the semiconductor substrate 201a by the ion implantation process. The photoelectric conversion region 210a may be doped with impurities (e.g., n-type impurities) of an opposite conductivity type to that of the semiconductor substrate 201a. The photoelectric conversion region 210a may be formed by laminating a plurality of doped regions.

In at least one example embodiment, the doping density of the photoelectric conversion region 210a in the CMOS image sensor operated by the method according to some example embodiments may be lower than the doping density of the photoelectric conversion region in the conventional CMOS image sensor. For example, the photoelectric conversion region 210a may be relatively lightly doped with n-type impurities, and thus the charge storage capacity of the photoelectric conversion regions 210a may be lower than a charge storage capacity of the photoelectric conversion region in the conventional CMOS image sensor.

In at least one example embodiment, isolation regions 203a may be formed among the plurality of unit pixels. The isolation regions may be formed using a field oxide (FOX) by a shallow trench isolation (STI) process or a local oxidation of silicon (LOCOS) process.

The floating diffusion region 230a may be formed in the semiconductor substrate 201a by the ion implantation process. The contact 235a may be formed on the floating diffusion region 230a for electrically connecting the floating diffusion region 230a and the output unit 270a in FIG. 4.

In at least one example embodiment, the floating diffusion region 230a may have a structure for reducing a leakage current, as described below with reference to FIG. 20. The structure of the floating diffusion region 230a according to some example embodiments may be referred to as a low dark level structure. In the conventional CMOS image sensor, the floating diffusion region has a dark level that is much higher than (e.g., at least ten times as high as) a dark level of the photoelectric conversion region. In the CMOS image sensor operated by the method according to some example embodiments, a dark level of the floating diffusion region 230a may be substantially the same as a dark level of the photoelectric conversion region 210a. That is, the dark level of the floating diffusion region 230a may be lower than the dark level of the floating diffusion region in the conventional CMOS image sensor.

The transfer gate 220a may be formed over the semiconductor substrate 201a, and may be disposed between the photoelectric conversion region 210a and the floating diffusion region 230a. A contact may be formed on the transfer gate 220a for receiving the transfer signal TX. The reset gate 240a may be formed over the semiconductor substrate 201a, and may be disposed between the floating diffusion region 230a and the reset drain 245a. A contact may be formed on the reset gate 240a for receiving the reset signal RST, and a contact may be formed on the reset drain 245a for receiving the power supply voltage VDD. Although not illustrated in FIG. 5, an insulation layer (not illustrated) including the gates 220a and 240a and the contacts may be formed over the semiconductor substrate 201a.

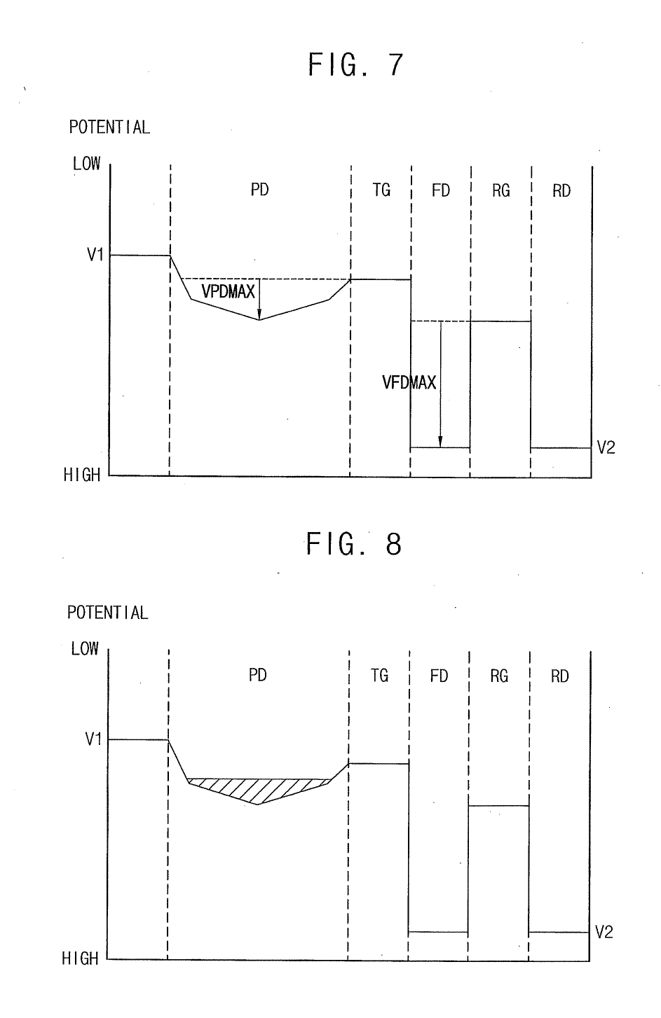

FIGS. 6, 7, 8 and 9 are diagrams for describing operations of the unit pixel of FIG. 5 operated by the method of FIG. 1.

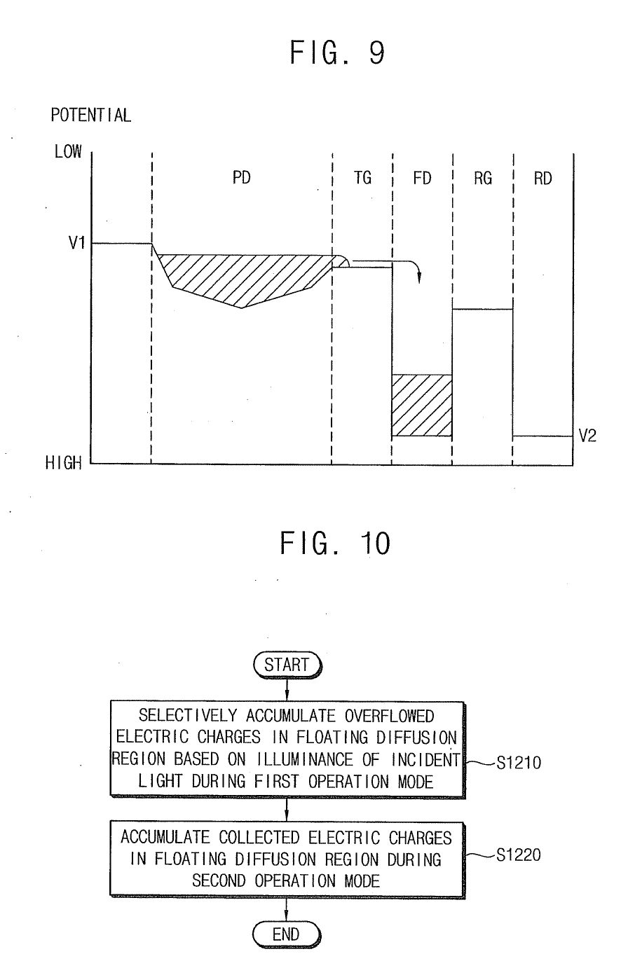

FIG. 6 is a diagram illustrating a potential level of the unit pixel in the conventional CMOS image sensor during the first operation mode. FIG. 7 is a diagram illustrating a potential level of the unit pixel 200a of FIG. 5 during the first operation mode. FIG. 8 is a diagram illustrating the potential level of the unit pixel 200a of FIG. 5 when the overflowed electric charges are not generated during the first operation mode. FIG. 9 is a diagram illustrating the potential level of the unit pixel 200a of FIG. 5 when the overflowed electric charges are generated during the first operation mode.

In FIGS. 6, 7, 8 and 9, a positive direction of Y-axis corresponds to a direction where a potential level becomes lower and an electron has higher energy. For example, a level of a voltage V1 may correspond to a ground voltage level (e.g., about 0V), and a level of a voltage V2 may correspond to a power supply voltage level (e.g., about 2.8V).

Referring to FIG. 6, in the unit pixel of the conventional CMOS image sensor, the photoelectric conversion region is relatively heavily doped with impurities for increasing a dynamic range of the conventional CMOS image sensor. The conventional photoelectric conversion region has the relatively large charge storage capacity. In FIG. 6, VPDMAX0 indicates the charge storage capacity of the conventional photoelectric conversion region, and a magnitude of the VPDMAX0 may have in a range of about 1.5V to about 2V.

However, the dark level performance of the conventional CMOS image sensor is degraded and the image lag phenomenon occurs in the conventional CMOS image sensor due to the relatively large charge storage capacity. In addition, in the unit pixel of the conventional CMOS image sensor, the reset signal is activated during the whole of the first operation mode, the reset gate has an electric potential level that is substantially the same as an electric potential level of the floating diffusion region, and thus the overflowed electric charges are not accumulated in the floating diffusion region during the first operation mode.

Referring to FIGS. 5 and 7, in the unit pixel 200a of FIG. 5 according to some example embodiments, the photoelectric conversion region 210a is relatively lightly doped with impurities (e.g., n-type impurities). The charge storage capacity of the photoelectric conversion regions 210a may be lower than the charge storage capacity of the conventional photoelectric conversion region. In FIG. 7, VPDMAX indicates the charge storage capacity of the photoelectric conversion region 210a. A magnitude of the VPDMAX may be smaller than the magnitude of the VPDMAX0. For example, the magnitude of the VPDMAX may be about 1.0V.

The CMOS image sensor 100 including the photoelectric conversion regions 210a may have the improved dark level performance, and the image lag phenomenon may be reduced because of the relatively small charge storage capacity. In the unit pixel 200a of FIG. 5, the reset signal RST is deactivated during a part of the first operation mode, and the reset gate 240a has an electric potential level that is lower than an electric potential level of the floating diffusion region 230a. Thus, the floating diffusion region 230a may have a potential well and the overflowed electric charges may be accumulated in the floating diffusion region 230a during the part of the first operation mode. In FIG. 7, VFDMAX indicates the charge storage capacity of the floating diffusion region 230a. A magnitude of the VFDMAX may be larger than the magnitude of the VPDMAX.

Referring to FIG. 8, if the incident light has a relatively low illuminance, all of the electric charges generated by the incident light are collected in the photoelectric conversion region 210a. The collected electric charges are generated in the photoelectric conversion region 210a and the overflowed electric charges are not generated. In this case, an image signal generated from the CMOS image sensor may correspond to a quantity of the collected electric charges.

Referring to FIG. 9, if the incident light has a relatively high illuminance, the electric charges generated by the incident light are collected in the photoelectric conversion region 210a in an initial operation time. When the number of the electric charges generated by the incident light may be larger than the number of electric charges corresponding to the charge storage capacity of the photoelectric conversion region 210a, some electric charges are overflowed from the photoelectric conversion region 210a. That is, the collected electric charges are generated in the photoelectric conversion region 210a and the overflowed electric charges are also generated. The overflowed electric charges are accumulated in the floating diffusion region 230a. In this case, an image signal generated from the CMOS image sensor may correspond to the quantity of the collected electric charges and a quantity of the overflowed electric charges.

FIG. 10 is a flow chart illustrating an example of accumulating at least one of the collected electric charges and the overflowed electric charges of FIG. 1.

Referring to FIG. 10, in the step S1200, the overflowed electric charges may be selectively accumulated in the floating diffusion region based on the illuminance of the incident light during the first operation mode (step S1210), and the collected electric charges may be accumulated in the floating diffusion region during the second operation mode (step S1220).

FIG. 11 is a flow chart illustrating an example of selectively accumulating the overflowed electric charges of FIG. 10.

Referring to FIG. 11, in the step S1210, the floating diffusion region may be reset during a first period of the first operation mode (step S1211), and it is determined that whether or not the illuminance of the incident light is higher than the reference illuminance (step S1213). When the illuminance of the incident light is higher than the reference illuminance (i.e., when the overflowed electric charges are generated), the overflowed electric charges may be accumulated in the floating diffusion region during a second period of the first operation mode (step S1215). When the illuminance of the incident light is lower than the reference illuminance (i.e., when the overflowed electric charges are not generated), the reset state of the floating diffusion region may be maintained during the second period of the first operation mode (step S1217). The first period of the first operation mode may be referred to as a first reset period, and the second period of the first operation mode may be referred to as a first accumulation period.

In at least one example embodiment, the unit pixel may include the reset gate that resets the floating diffusion region in response to the reset signal, as described above with reference to FIGS. 4 and 5. The reset signal may be activated during the first period of the first operation mode, and may be deactivated during the second period of the first operation mode. The reference illuminance may have different values depending on a size of the photoelectric conversion region, the doping density of the photoelectric conversion region, the time duration of the first operation mode, etc.

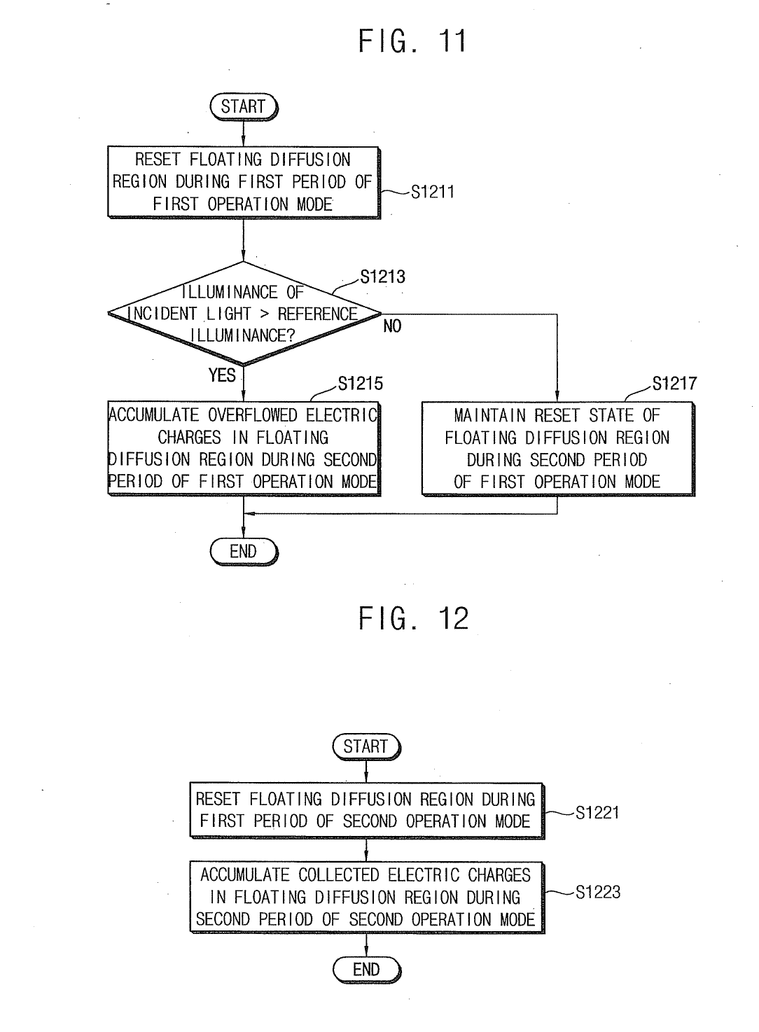

FIG. 12 is a flow chart illustrating an example of accumulating the collected electric charges of FIG. 10.

Referring to FIG. 12, in the step S1220, the floating diffusion region may be reset during a first period of the second operation mode (step S1221), and the collected electric charges may be accumulated in the floating diffusion region during a second period of the second operation mode (step S1223). The first period of the second operation mode may be referred to as a second reset period, and the second period of the second operation mode may be referred to as a second accumulation period.

In at least one example embodiment, the unit pixel may include the reset gate that resets the floating diffusion region in response to the reset signal and the transfer gate that transfers the collected electric charges to the floating diffusion region in response to the transfer signal, as described above with reference to FIGS. 4 and 5. The reset signal may be activated during the first period of the second operation mode, and the transfer signal may be activated during the second period of the second operation mode.

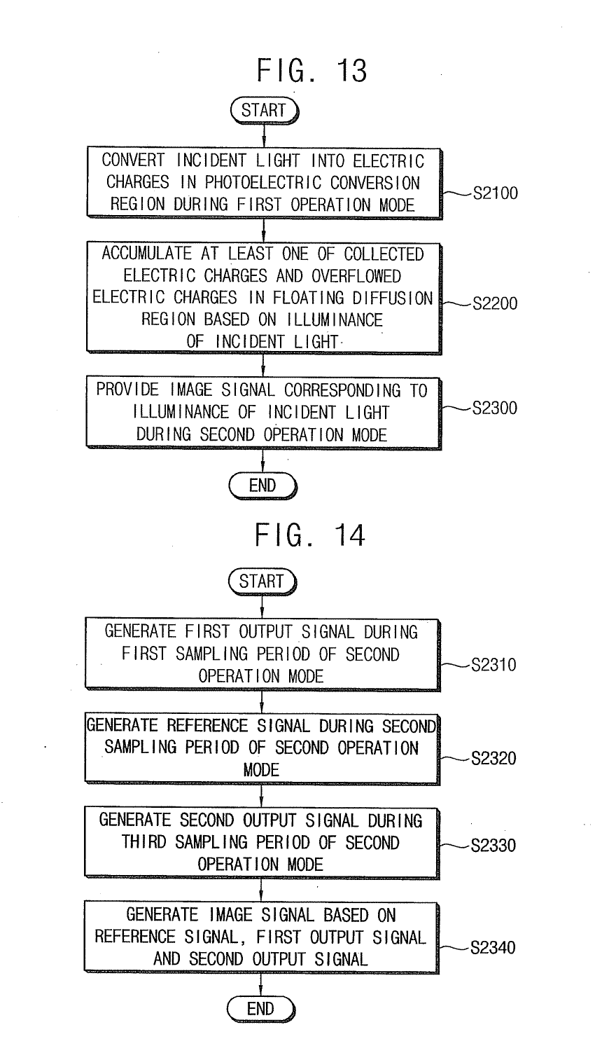

FIG. 13 is a flow chart illustrating a method of driving an image sensor according to other example embodiments.

Referring to FIG. 13, in the method of driving the image sensor according to other example embodiments, the incident light is converted into electric charges in the photoelectric conversion region during the first operation mode (step S2100). At least one of the collected electric charges and the overflowed electric charges is accumulated in the floating diffusion region based on the illuminance of the incident light (step S2200). An image signal corresponding to the illuminance of the incident light is provided during the second operation mode (step S2300). The step S2100 and the step S2200 may be substantially the same as the step S1100 and the step S1200 in FIG. 1, respectively.

FIG. 14 is a flow chart illustrating an example of providing the image signal of FIG. 13.

Referring to FIG. 14, in the step S2300, a first output signal may be generated by sampling an electric potential of the floating diffusion region during a first sampling period of the second operation mode (step S2310). A reference signal may be generated by sampling the electric potential of a reset state of the floating diffusion region during a second sampling period of the second operation mode (step S2320). A second output signal may be generated by sampling the electric potential of the floating diffusion region during a third sampling period of the second operation mode (step S2330). The image signal may be generated based on the reference signal, the first output signal and the second output signal (step S2340).

In at least one example embodiment, the first output signal may correspond to one of the overflowed electric charges and the electric potential of the reset state of the floating diffusion region. For example, the first output signal may correspond to the overflowed electric charges when the illuminance of the incident light is higher than the reference illuminance, and may correspond to the electric potential of the reset state of the floating diffusion region when the illuminance of the incident light is lower than the reference illuminance. The second output signal may correspond to the collected electric charges.

In at least one example embodiment, the first sampling period of the second operation mode may be prior to the first period of the second operation mode (i.e., the second reset period). The second sampling period of the second operation mode may be later than the first period of the second operation mode and may be prior to the second period of the second operation mode (i.e., the second accumulation period). The third sampling period of the second operation mode may be later than the second period of the second operation mode.

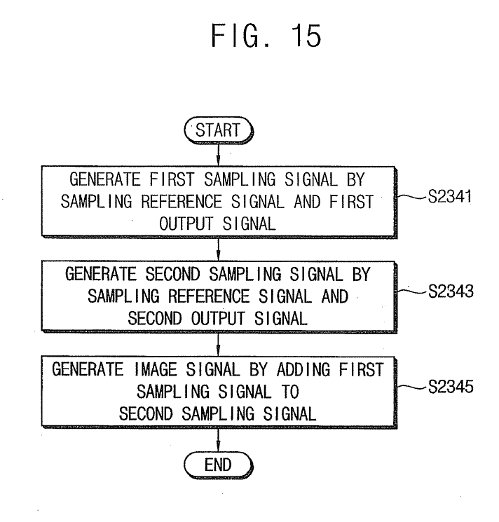

FIG. 15 is a flow chart illustrating an example of generating the image signal of FIG. 14.

Referring to FIG. 15, in the step S2340, a first sampling signal may be generated by performing correlated double sampling on the reference signal and the first output signal (step S2341). A second sampling signal may be generated by performing the correlated double sampling on the reference signal and the second output signal (step S2343). The image signal may be generated by adding the first sampling signal to the second sampling signal (step S2345).

In at least one example embodiment, the image signal may have different levels depending on the illuminance of the incident light. For example, the level of the image signal may correspond to the quantity of the collected electric charges when the illuminance of the incident light is lower than the reference illuminance. The level of the image signal may correspond to a sum of the quantity of the collected electric charges and the quantity of the overflowed electric charges when the illuminance of the incident light is higher than the reference illuminance.

The method of driving the image sensor according to some example embodiments may be applied to a front-side illumination CMOS image sensor (FIS) and a back-side illumination CMOS image sensor (BIS). In addition, the method of driving the image sensor according to some example embodiments may be applied to image sensors of a global shutter type or a rolling shutter type. For example, when a still image is captured in an image sensor of the global shutter type, a shutter may be open for all rows of pixels during the integration mode, and the read voltage may be applied to the transfer gates of each row in row-by-row order during the readout mode. In an image sensor of the rolling shutter type, operations of the integration mode and the readout mode are repeated for each row.

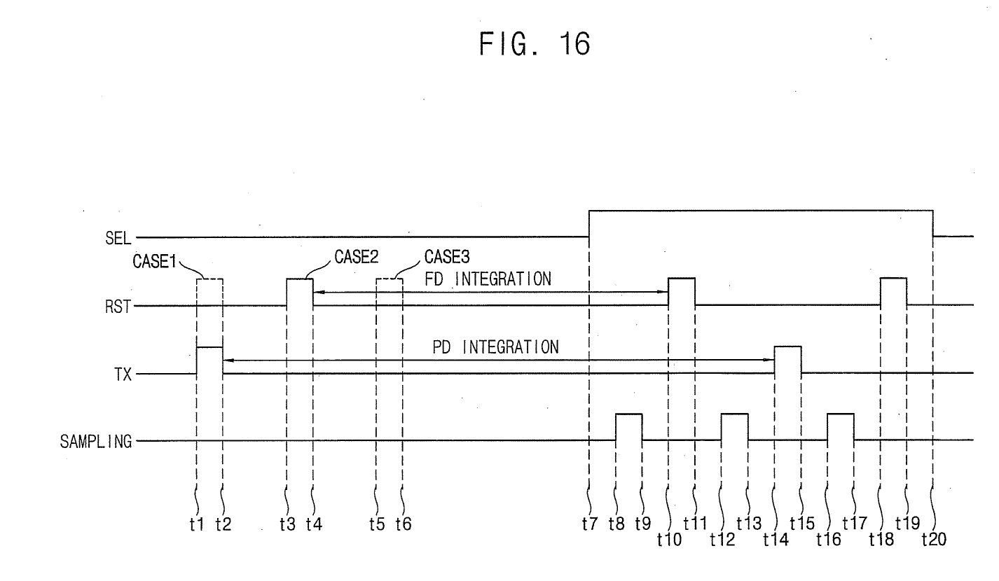

FIG. 16 is a timing diagram for describing the method of driving the image sensor according to some example embodiments.

Hereinafter, the method of driving the image sensor according to some example embodiments will be described with reference to FIGS. 1 through 5 and 10 through 16.

The CMOS image sensor 100 of FIG. 2 operated by the method of driving the image sensor according to some example embodiments includes a plurality of unit pixels arranged in a matrix form. Each unit pixel includes the photoelectric conversion region 210a, the transfer gate 220a, the floating diffusion region 230a, the reset gate 240a and the output unit 270a, as illustrated in FIGS. 4 and 5. To improve the dark level performance and reduce the image lag phenomenon, the photoelectric conversion region 210a is relatively lightly doped with n-type impurities, and thus the charge storage capacity of the photoelectric conversion regions 210a may be lower than the charge storage capacity of the photoelectric conversion region in the conventional CMOS image sensor. The CMOS image sensor 100 operates alternatively in two modes. During the first operation mode (i.e., the integration mode), image information on an object to be captured is obtained by collecting charge carriers in the photoelectric conversion region 210a. During the second operation mode (i.e., the readout mode), the image information in a form of charge carriers is converted into electrical signals.

During a time period from time t1 to time t2, the transfer signal TX is activated. At time t2, the transfer signal TX is deactivated, the shutter of the CMOS image sensor 100 is opened, and the CMOS image sensor 100 starts to operate in the first operation mode. During the first operation mode, the incident light is converted into electric charges in the photoelectric conversion region 210a.

The reset signal RST is not activated during the entire first operation mode, but may be selectively activated during at least a portion of the first operation mode. The reset signal RST is activated during the first period of the first operation mode (i.e., the first reset period) to reset the floating diffusion region 230a. The reset signal RST is deactivated during the second period of the first operation mode (i.e., the first accumulation period) to allow the overflowed electric charges to be accumulated in the floating diffusion region 230a. For example, in CASE2 shown in a solid line, the first reset period may be a time period from time t3 to time t4 and the first accumulation period may be a time period from time t4 to time t10. During the time period from time t3 to time t4, the reset signal RST is activated and the floating diffusion region 230a is reset. During the time period from time t4 to time t10, the reset signal RST is deactivated, and the overflowed electric charges are selectively accumulated in the floating diffusion region 230a based on the illuminance of the incident light. For example, the overflowed electric charges are accumulated in the Do' diffusion region 230a when the illuminance of the incident light is higher than the reference illuminance. The reset state of the floating diffusion region 230a is maintained when the illuminance of the incident light is lower than the reference illuminance. The electric charges, which are generated in the photoelectric conversion region 210a and are not overflowed from the photoelectric conversion region 210a, are collected in the photoelectric conversion region 210a as the collected electric charges.

The dynamic range of the CMOS image sensor 100 may be determined based on a ratio of a PD integration period to a FD integration period. For example, in CASE2 shown in a solid line, the FD integration period may be the time period from time t4 to time t10. That is, the FD integration period may correspond to the first accumulation period. The PD integration period may be a time period from time t2 to time t14.

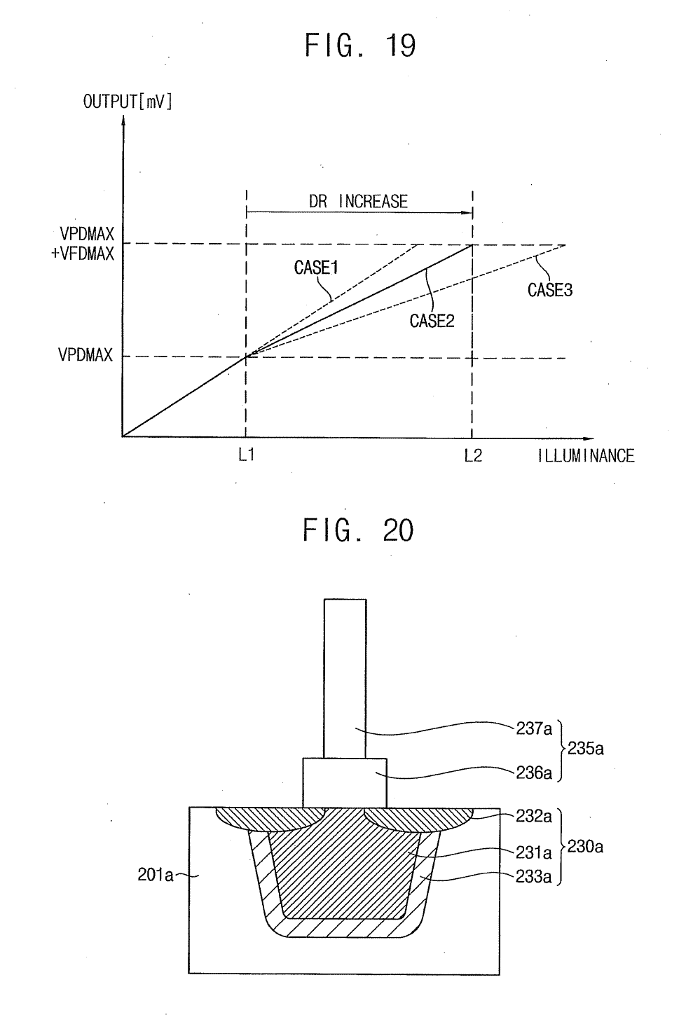

In at least one example embodiment, the timing controller 129 included in the CMOS image sensor 100 may change a start time point of the first reset period and a start time point of the first accumulation period. For example, in CASE1 shown in a dotted line, the first reset period may be changed to the time period from time t1 to time t2 and the first accumulation period may be changed to a time period from time t2 to time t10. In this case, the overflowed electric charges are accumulated in the floating diffusion region 230a during the time period from time t2 to time t10. In CASE3 shown in a dotted line, the first reset period may be changed to a time period from time t5 to time t6 and the first accumulation period may be changed to a time period from time t6 to time t10. In this case, the overflowed electric charges are accumulated in the floating diffusion region 230a during the time period from time t6 to time t10. As described below with reference to FIGS. 18 and 19, the dynamic range of the CMOS image sensor 100 may be controlled by changing the start time point of the first reset period.

At time t7, the select signal SEL is activated and the unit pixel for providing the image signal is selected. The CMOS image sensor 100 starts to operate in the second operation mode. The first operation mode and the second operation mode may be partially overlapped. During the first sampling period (e.g., from time t8 to time t9) of the second operation mode, the output unit 270a generates the first output signal by sampling an electric potential of the floating diffusion region 230a. When the overflowed electric charges are accumulated in the floating diffusion region 230a during the first accumulation period, the first output signal may correspond to the quantity of the overflowed electric charges. When the overflowed electric charges are not accumulated in the floating diffusion region 230a during the first accumulation period, the first output signal may correspond to the electric potential of the reset state of the floating diffusion region 230a.

During the first period of the second operation mode, which is the second reset period (e.g., from time t10 to time t11), the reset signal RST is activated and the floating diffusion region 230a is reset. When the overflowed electric charges are accumulated in the floating diffusion region 230a during the first accumulation period, the overflowed electric charges may be discharged and the floating diffusion region 230a becomes the reset state. When the overflowed electric charges are not accumulated in the floating diffusion region 230a during the first accumulation period, the reset state of the floating diffusion region 230a is maintained. During the second sampling period (e.g., from time t12 to time t13) of the second operation mode, the output unit 270a generates a reference signal by sampling the electric potential of the reset state of the floating diffusion region 230a. The reference signal may be used for performing the CDS operation.

During the second period of the second operation mode, which is the second accumulation period (e.g., from time t14 to time t15), the transfer signal TX is activated and the collected electric charges are transferred from the photoelectric conversion region 210a to the floating diffusion region 230a. The collected electric charges are accumulated in the floating diffusion region 230a. During the third sampling period (e.g., from time t16 to time t17) of the second operation mode, the output unit 270a generates the second output signal by sampling the electric potential of the floating diffusion region 230a. The second output signal may correspond to the quantity of the collected electric charges.

During a time period from time 18 to time 19, the reset signal RST is activated, the collected electric charges may be discharged, and the floating diffusion region 230a is reset. At time t20, the select signal SEL is deactivated and thus the second operation mode is over.

In at least one example embodiment, the signal processing unit 120 generates the image signal based on the reference signal, the first output signal and the second output signal during the second operation mode.

The CDS unit 122 performs the CDS operation on the reference signal and the first output signal to generate the first sampling signal, and performs the CDS operation on the reference signal and the second output signal to generate the second sampling signal. For example, the CDS unit 122 may generate the first sampling signal by subtracting the reference signal from the first sampling signal, and may generate the second sampling signal by subtracting the reference signal from the second sampling signal.

In the operation of generating the second sampling signal, the floating diffusion region 230a is reset and the reference signal is generated based on a current reset state. After the reference signal is generated, the collected electric charges are transferred from the photoelectric conversion region 210a to the floating diffusion region 230a, and then the second output signal is generated based on the current reset state. Thus, the second sampling signal may be generated based on a true CDS operation because both of the reference signal and the second output signal are generated based on the current reset state.

In the operation of generating the first sampling signal, the overflowed electric charges are transferred from the photoelectric conversion region 210a to the floating diffusion region 230a, and the first output signal is generated based on a previous reset state. After the first output signal is generated, the floating diffusion region 230a is reset and the reference signal is generated based on the current reset state. Thus, the first sampling signal may be generated based on an untrue CDS operation because the first output signal is generated based on the previous reset state and the reference signal is generated based on the current reset state. The first sampling signal may include a noise signal due to the untrue CDS operation. However, a level of the noise signal may be much lower than a level of the first sampling signal, and thus an influence of the noise signal may be neglected.

The ADC unit 123 adds the first sampling signal to the second sampling signal and converts the added signal into a digital signal to provide the image signal. The buffer unit 127 included in the ADC unit 123 may store the first sampling signal before until the second sampling signal is generated. The buffer unit 127 may be implemented with a plurality of single line buffers because a time interval between a time point at which the first sampling signal is generated (e.g., at time t13) and a time point at which the second sampling signal is generated (e.g., at time t17) is relatively short. In the operation of generating the first sampling signal, a quantization noise of the ADC unit 123 may be reduced by increasing a gain of the ADC unit 123, and thus the dynamic range of the CMOS image sensor 100 may increase.

In the method of driving the image sensor according to some example embodiments, timing of the reset signal RST is controlled in the first and second operation modes, and the overflowed electric charges and the collected electric charges are sequentially accumulated in the floating diffusion region 230a. The first output signal is generated based on the overflowed electric charges, the second output signal is generated based on the collected electric charges, and the image signal is generated based on the first and second output signals. Thus, the image sensor operated by the method according to some example embodiments may have a wide dynamic range and improved performances.

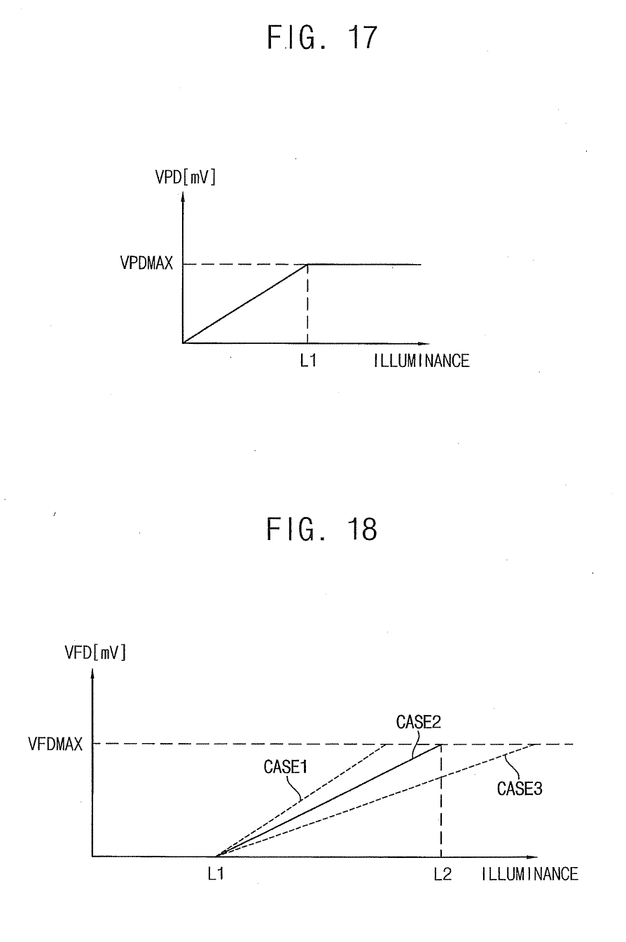

FIGS. 17, 18 and 19 are diagrams for describing the method of driving the image sensor according to some example embodiments.

FIG. 17 illustrates a variation of a voltage level of the photoelectric conversion region 210a during the first operation mode, according to the illuminance of the incident light. FIG. 18 illustrates a variation of a voltage level of the floating diffusion region 230a during the first operation mode, according to the illuminance of the incident light. FIG. 19 illustrates a voltage level of the output image signal of the image sensor, according to the illuminance of the incident light. CASE1, CASE2 and CASE3 in FIGS. 18 and 19 correspond to CASE1, CASE2 and CASE3 in FIG. 16, respectively.

Referring to FIG. 17, as the illuminance of the incident light increases, the number of electric charges that are generated and collected in the photoelectric conversion region 210a increases, and thus the voltage level of the photoelectric conversion region 210a also increases. When the illuminance of the incident light corresponds to a reference illuminance L1, the voltage level of the photoelectric conversion region 210a corresponds to a maximum level VPDMAX. Although the illuminance of the incident light is higher than the reference illuminance L1, the voltage level of the photoelectric conversion region 210a maintains the maximum level VPDMAX because the charge storage capacity of the photoelectric conversion region 210a is fixed. The overflowed electric charges, which are not collected in the photoelectric conversion region 210a, are generated and move toward the floating diffusion region 230a.

Referring to FIG. 18, when the illuminance of the incident light is higher than the reference illuminance L1, the overflowed electric charges are accumulated in the floating diffusion region 230a, and thus the voltage level of the floating diffusion region 230a increases. The voltage level of the floating diffusion region 230a increases until the voltage level of the floating diffusion region 230a reaches the maximum level VFDMAX. For example, in CASE2 shown in a solid line, when the illuminance of the incident light corresponds to a limitation illuminance L2, the voltage level of the floating diffusion region 230a corresponds to a maximum level VFDMAX. The maximum level VFDMAX may be higher than the maximum level VPDMAX.

In at least one example embodiment, a slope of the variation of the voltage level of the floating diffusion region 230a may be controlled by changing the start time point of the first period of the first operation mode (i.e., the first reset period). For example, in CASE1 shown in a dotted line, when a time period during which the transfer signal TX is activated and the first reset period simultaneously occur, the slope of the variation of the voltage level of the floating diffusion region 230a may be substantially the same as a slope of the variation of the voltage level of the photoelectric conversion region 210a in FIG. 17. As the start time point of the first reset period is delayed such as CASE2 or CASE3, that is, as the time duration of the FD integration period is short, the slope of the variation of the voltage level of the floating diffusion region 230a may decrease, as illustrated in FIG. 18.

Referring to FIG. 19, the voltage level of the output image signal may be calculated by adding the voltage level of the photoelectric conversion region 210a (illustrated in FIG. 17) to the voltage level of the floating diffusion region 230a (illustrated in FIG. 18). The CMOS image sensor operated by the method according to some example embodiments may have a wide dynamic range. In CASE2 shown in a solid line, the dynamic range of the CMOS image sensor operated by the method according to some example embodiments may be larger than the dynamic range of the conventional CMOS image sensor by (L2-L1). For example, the CMOS image sensor operated by the method according to some example embodiments may have a wide dynamic range of above about 100 dB, while the conventional CMOS image sensor has a dynamic range of about 60 dB.

In the image sensor operated by the method according to some example embodiments, the slope of the variation of the voltage level of the floating diffusion region 230a is controlled by changing the start time point of the first reset period, and thus the dynamic range of the image sensor may be effectively controlled. In addition, since the output image signal is calculated by adding the voltage level of the photoelectric conversion region 210a to the voltage level of the floating diffusion region 230a, a SNR dip phenomenon, which indicates the SNR curve of the output image signal having discontinuous value at the reference illuminance, may be prevented, and thus the image sensor may have improved performance.

In FIGS. 17, 18 and 19, although Y-axis corresponds to an analog voltage level, the Y-axis may correspond to the number of generated electric charge (i.e., the quantity of the electric charge), the charge storage capacity and a digital voltage level, etc.

FIG. 20 is an enlarged view of a portion “A” in FIG. 5.

Referring to FIGS. 5 and 20, the floating diffusion region 230a may include a first impurity region 231a, a second impurity region 232a and a third impurity region 233a. The floating diffusion region 230a may have a low dark level structure for reducing a leakage current. The contact 235a may include a first electrode portion 236a and a second electrode portion 237a.

The first impurity region 231a may be formed at a surface portion of the semiconductor substrate 201a. The second impurity region 232a may be formed at the surface portion of the semiconductor substrate 201a. The second impurity region 232a may be formed adjacent to the first impurity region 231a. For example, the second impurity region 232a may be partially overlapped with the first impurity region 231a. The first impurity region 231a may be partially exposed to outside (e.g., insulation layer) of the semiconductor substrate 201a due to the second impurity region 232a. Thus, an exposed surface area of the first impurity region 231a may be reduced, and a leakage current that flows from the first impurity region 231a to the outside of the semiconductor substrate 201a may be reduced.

The third impurity region 233a may be formed in the semiconductor substrate 201a. The third impurity region 233a may be formed adjacent to the first impurity region 231a and the second impurity region 232a. The first impurity region 231a may be surrounded by the third impurity region 233a, and may not be directly contacted with the semiconductor substrate 201a. Thus, a leakage current that flows from the first impurity region 231a to inside of the semiconductor substrate 201a may be reduced.

In at least one example embodiment, the second impurity region 232a may be doped with impurities of a same conductivity type to that of the semiconductor substrate 201a. For example, the semiconductor substrate 201a and the second impurity region 232a may be doped with p-type impurities. A doping density of the second impurity region 232a may be higher than a doping density of the semiconductor substrate 201a. For example, the second impurity region 232a may be (p+)-type region and the semiconductor substrate 201a may be (p−)-type region.

The first impurity region 231a and the third impurity region 233a may be doped with impurities of an opposite conductivity type to that of the semiconductor substrate 201a. For example, the first impurity region 231a and the third impurity region 233a may be doped with n-type impurities. A doping density of the first impurity region 231a may be higher than a doping density of the third impurity region 233a. For example, the first impurity region 231a may be (n+)-type region and the third impurity region 233a may be (n−)-type region. In this case, the photoelectric conversion region 210a of FIG. 5 may be doped with n-type impurities, and the doping density of the photoelectric conversion region 210a may be lower than the doping density of the first impurity region 231a. For example, the photoelectric conversion region 210a may be (n−)-type region.

In the image sensor according to some example embodiments, the floating diffusion region 230a may have the low dark level structure, as illustrated in FIG. 20. For example, the floating diffusion region 230a may include the first impurity region 231a to accumulate the overflowed electric charges or the collected electric charges, and further include the second and third regions 232a and 233a to reduce the leakage current. Thus, the image sensor may have the improved dark level performance. Although an example of the low dark level structure for the floating diffusion region 230a is illustrated in FIG. 20, the floating diffusion region in the image sensor may have various structures for reducing the leakage current.

In at least one example embodiment, the floating diffusion region 230a may be generated in the order of the third impurity region 233a, the first impurity region 231a and the second impurity region 232a. For example, at first, the third impurity region 233a may be formed by implanting (n−)-type impurities in the semiconductor substrate 201a. Next, the first impurity region 231a may be formed by implanting (n+)-type impurities in the semiconductor substrate 201a, and then the second impurity region 232a may be formed by implanting (p+)-type impurities in the semiconductor substrate 201a.

The first electrode portion 236a may be formed on the semiconductor substrate 201a. For example, the first electrode portion 236a may be formed on the exposed surface of the first impurity region 231a. The first electrode portion 236a may be formed using, for example, polysilicon doped with impurities. The second electrode portion 237a may be formed on the first electrode portion 236a and may include a conductive material such as a metal and/or metal compound. For example, the second electrode portion 237a may include iridium (Ir), ruthenium (Ru), rhodium (Rh), palladium (Pd), aluminum (Al), silver (Ag), platinum (Pt), titanium (Ti), tantalum (Ta), tungsten (W), aluminum nitride (AlNx), titanium nitride (TiNx), tantalum nitride (TaNx), tungsten nitride (WNx), etc. These may be used alone or in a combination thereof.

In at least one example embodiment, the contact 235a may be generated in the order of the first electrode portion 236a and the second electrode portion 237a. For example, an insulation layer (not illustrated) may be formed over the semiconductor substrate 201a, a first recess may be formed at the insulation layer by an etching process, and then the first electrode portion 236a may be formed on the exposed surface of the first impurity region 231a to fill a lower portion of the first recess with polysilicon. The second electrode portion 237a may be formed on the first electrode portion 236a to fill an upper portion of the first recess with metal and/or metal compound. For another example, the first electrode portion 236a may be formed on the exposed surface of the first impurity region 231a with polysilicon, the insulation layer may be formed over the semiconductor substrate 201a and the first electrode portion 236a, and then a second recess may be formed at the insulation layer by the etching process to expose the first electrode portion 236a. The second electrode portion 237a may be formed on the first electrode portion 236a to fill the second recess with metal and/or metal compound.

In the CMOS image sensor according to some example embodiments, the contact 235a may include the first electrode portion 236a for shock absorbing. The semiconductor substrate 201a may not be directly contacted with metal and/or metal compound included in the second electrode portion 237a. The first electrode portion 236a may reduce damage of the semiconductor substrate 201a due to the etching process. In addition, the first electrode portion 236a may provide an ohmic contact to improve an electrical performance of the floating diffusion 230a and the semiconductor substrate 201a. Thus, the CMOS image sensor may have improved performance.

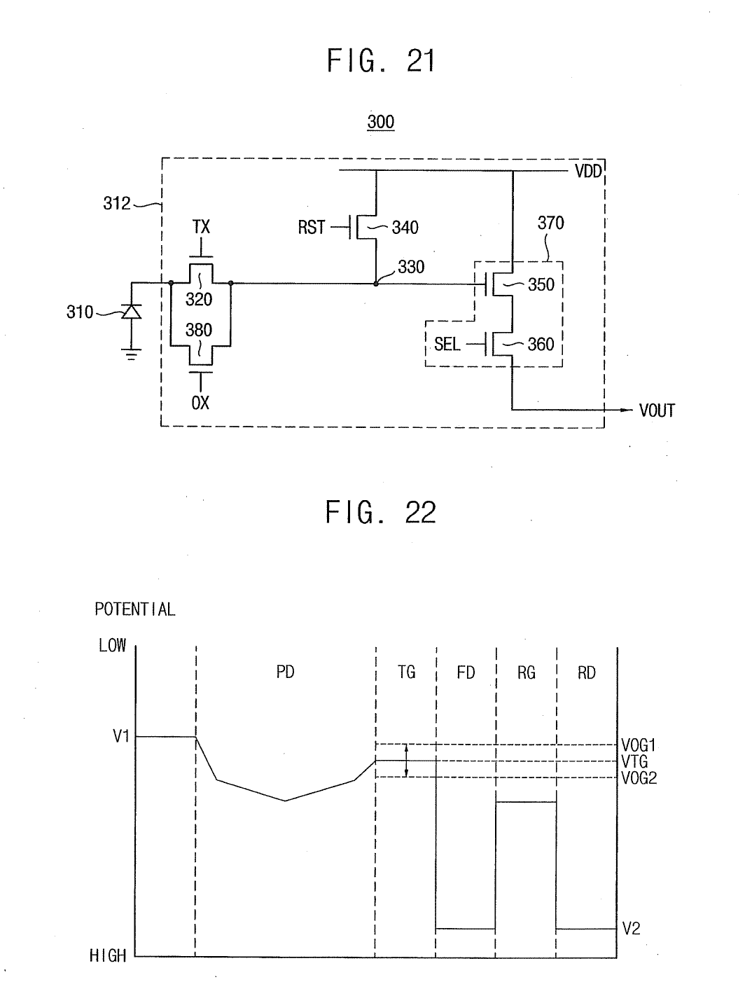

FIG. 21 is a circuit diagram illustrating another example of the unit pixel included in the CMOS image sensor of FIG. 2.

Referring to FIG. 21, the unit pixel 300 may include a photoelectric conversion element 310 and a signal generation unit 312. The signal generation unit 312 may include a transfer transistor 320, a reset transistor 340, a drive transistor 350, a select transistor 360, an overflow transistor 380 and a floating diffusion node 330. The drive transistor 350 and the select transistor 360 may be part of an output unit 370.

The photoelectric conversion element 310, the signal generation unit 312, the transfer transistor 320, the reset transistor 340, the drive transistor 350, the select transistor 360 and the floating diffusion node 330 may have the same structure and/or operation as the photoelectric conversion element 210, the signal generation unit 212, the transfer transistor 220, the reset transistor 240, the drive transistor 250, the select transistor 260 and the floating diffusion node 230 in FIG. 3, respectively.

The overflow transistor 380 may be connected to the photoelectric conversion element 310 and the floating diffusion node 330, and may have a gate electrode receiving an overflow signal OX. The overflow transistor 380 may transfer the overflowed electric charges from the photoelectric conversion element 310 to the floating diffusion node 330. The overflow transistor 380 may have a threshold voltage that is the same as or different from a threshold voltage of the transfer transistor 320. The overflow signal OX may have a fixed voltage level during the first and second operation modes. The voltage level of the overflow signal OX may be changed after the second operation mode if the charge storage capacity of the photoelectric conversion element 310 needs to be changed.

If the CMOS image sensor includes the unit pixel 300 of FIG. 21, the method of driving the image sensor according to some example embodiments may further include a step of controlling the charge storage capacity of the photoelectric conversion region by adjusting the voltage level of the overflow signal OX. That is, in the method of driving the image sensor including the unit pixel 300 of FIG. 21, the incident light is converted into electric charges in the photoelectric conversion region during the first operation mode, at least one of the collected electric charges and the overflowed electric charges is accumulated in the floating diffusion region based on the illuminance of the incident light, and the charge storage capacity of the photoelectric conversion region is controlled by adjusting the voltage level of the overflow signal OX.

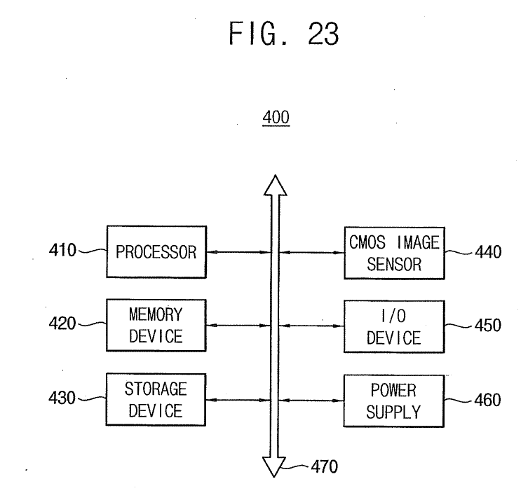

FIG. 22 is a diagram for describing an operation of the unit pixel of FIG. 21 operated by the method of FIG. 1. FIG. 22 is a diagram illustrating a potential level of the unit pixel 300 of FIG. 21 during the first operation mode.

Referring to FIGS. 21 and 22, in the unit pixel 300 of FIG. 21 according to some example embodiments, the charge storage capacity of the photoelectric conversion region 310 may be controlled based on the voltage level of the overflow signal OX. When a threshold voltage of the transfer transistor 320 is substantially the same as the threshold voltage of the overflow transistor 380 e.g., a first threshold voltage VTG, the charge storage capacity of the photoelectric conversion region in the unit pixel 300 of FIG. 21 may be substantially the same as the charge storage capacity of the photoelectric conversion region in the unit pixel 200 of FIG. 3. When the threshold voltage of the overflow transistor 380 decreases from the first threshold voltage VTG to a second threshold voltage VOG1 based on the overflow signal OX, the charge storage capacity of the photoelectric conversion region in the unit pixel 300 of FIG. 21 may increase. When the threshold voltage of the overflow transistor 380 increases from the first threshold voltage VTG to a third threshold voltage VOG2 based on the overflow signal OX, the charge storage capacity of the photoelectric conversion region in the unit pixel 300 of FIG. 21 may decrease.

The CMOS image sensor according to some example embodiments may further include the overflow gate that is connected between the photoelectric conversion region and the floating diffusion region and connected in parallel with the transfer gate, as illustrated in FIG. 21. Thus, the overflowed electric charges may be effectively transferred from the photoelectric conversion region to the floating diffusion region by using the overflow gate, and the charge storage capacity of the photoelectric conversion region may be effectively controlled by adjusting the voltage level of the overflow signal.

FIG. 23 is a block diagram illustrating an electronic system having an image sensor according to some example embodiments.

Referring to FIG. 23, the electronic system 400 may include a processor 410, a memory device 420, a storage device 430, an image sensor 440 (e.g., a CMOS image sensor), an input/output (I/O) device 450, a power supply 460 and a bus 470. Although not illustrated in FIG. 23, the electronic system 400 may further include a plurality of ports for communicating with a video card, a sound card, a memory card, a universal serial bus (USB) device, other electronic systems, etc.

The processor 410 may perform various computing functions. The processor 410 may be a micro processor, a central processing unit (CPU), and etc. The processor 410 may be connected to the memory device 420, the storage device 430, and the I/O device 450 via the bus 470 including an address bus, a control bus, a data bus, etc. The processor 410 may be connected to an extended bus such as a peripheral component interconnection (PCI) bus.

The memory device 420 may store data for operations of the electronic system 400. For example, the memory device 420 may include a dynamic random access memory (DRAM) device, a static random access memory (SRAM) device, an erasable programmable read-only memory (EPROM) device, an electrically erasable programming read-only memory (EEPROM) device, a flash memory device, etc.

The storage device 430 may include a solid state drive device, a hard disk drive device, a CD-ROM device, etc. The I/O device 450 may include input devices such as a keyboard, a keypad, a mouse, etc, and output devices such as a printer, a display device, etc. The power supply 460 may provide a power for operations of the electronic system 400.

The image sensor 440 may communicate with the processor 410 via the bus 470 or other communication links. The image sensor 440 may be the CMOS image sensor 200 of FIG. 2 that includes one of the unit pixel 200 of FIG. 3, the unit pixel 200a of FIGS. 4 and 5 and the unit pixel 300 of FIG. 21. The image sensor 440 may be operated by the method of FIG. 1 or the method of FIG. 13. The image sensor 440 converts an incident light into electric charges in photoelectric conversion regions during a first operation mode, and accumulates at least one of collected electric charges and overflowed electric charges in floating diffusion regions based on illuminance of the incident light. The image sensor 440 may provide an image signal corresponding to the illuminance of the incident light during a second operation mode after the first operation mode, and may control a charge storage capacity of the photoelectric conversion region by adjusting a voltage level of a overflow signal.

In at least one example embodiment, the image sensor 440 and the processor 410 may be fabricated as one integrated circuit chip. In another example embodiment, the image sensor 440 and the processor 410 may be fabricated as two separate integrated circuit chips.

The above described embodiments may be applied to an image sensor, and an electronic system having the image sensor. For example, the electronic system may be a system using an image sensor such as a computer, a digital camera, a 3-D camera, a cellular phone, a personal digital assistant (PDA), a scanner, a navigation system, a video phone, a surveillance system, an auto-focusing system, a tracking system, a motion-sensing system, an image-stabilization system, etc.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A method of driving an image sensor, the method comprising:
converting incident light into electric charges in a photoelectric conversion region during a first operation mode; and
accumulating at least one of collected electric charges and overflowed electric charges in a floating diffusion region based on illuminance of the incident light, the collected electric charges indicating electric charges that are collected in the photoelectric conversion region, the overflowed electric charges indicating electric charges that have overflowed from the photoelectric conversion region.

2. The method of claim 1, wherein accumulating at least one of the collected electric charges and the overflowed electric charges includes:
selectively accumulating the overflowed electric charges in the floating diffusion region based on the illuminance of the incident light during the first operation mode; and
accumulating the collected electric charges in the floating diffusion region during a second operation mode after the first operation mode.

3. The method of claim 2, wherein selectively accumulating the overflowed electric charges includes:
resetting the floating diffusion region during a first period of the first operation mode;
accumulating the overflowed electric charges in the floating diffusion region during a second period of the first operation mode when the illuminance of the incident light is higher than a reference illuminance; and
maintaining the reset state of the floating diffusion region during the second period of the first operation mode when the illuminance of the incident light is lower than the reference illuminance.

4. The method of claim 3, wherein the image sensor includes a reset gate and the method further comprises:
resetting the floating diffusion region in response to a reset signal using the reset gate, the reset signal being activated during the first period of the first operation mode and being deactivated during the second period of the first operation mode.

5. The method of claim 3, wherein a dynamic range of the image sensor is controlled by changing a start time point of the first period of the first operation mode.

6. The method of claim 2, wherein accumulating the collected electric charges includes:
resetting the floating diffusion region during a first period of the second operation mode; and
accumulating the collected electric charges in the floating diffusion region during a second period of the second operation mode.

7. The method of claim 6, wherein the image sensor includes a reset gate and a transfer gate, and the method further includes:
resetting the floating diffusion region in response to a reset signal using the reset gate; and
transferring the collected electric charges from the photoelectric conversion region to the floating diffusion region based on a transfer signal using the transfer gate, the reset signal being activated during the first period of the second operation mode, the transfer signal being activated during the second period of the second operation mode.

8. The method of claim 1, further comprising:
providing an image signal corresponding to the illuminance of the incident light during a second operation mode after the first operation mode.

9. The method of claim 8, wherein providing the image signal includes:
generating a first output signal by sampling an electric potential of the floating diffusion region during a first sampling period of the second operation mode;
generating a reference signal by sampling the electric potential of a reset state of the floating diffusion region during a second sampling period of the second operation mode;
generating a second output signal by sampling the electric potential of the floating diffusion region during a third sampling period of the second operation mode; and
generating the image signal based on the reference signal, the first output signal and the second output signal.

10. The method of claim 9, wherein
the first output signal corresponds to the overflowed electric charges when the illuminance of the incident light is higher than a reference illuminance, and corresponds to the electric potential of the reset state of the floating diffusion region when the illuminance of the incident light is lower than the reference illuminance, and
the second output signal corresponds to the collected electric charges.

11. The method of claim 9, wherein generating the image signal includes:
generating a first sampling signal by performing correlated double sampling on the reference signal and the first output signal;
generating a second sampling signal by performing the correlated double sampling on the reference signal and the second output signal; and
generating the image signal by adding the first sampling signal to the second sampling signal.

12. The method of claim 11, wherein the image sensor includes a single line buffer storing the first sampling signal.

13. The method of claim 1, wherein the image sensor includes an overflow gate, the method further comprising:
transferring the overflowed electric charges from the photoelectric conversion region to the floating diffusion region using the overflow gate; and
controlling a charge storage capacity of the photoelectric conversion region by adjusting a voltage level of the overflow signal applied to the overflow gate.

14. The method of claim 1, wherein the floating diffusion region has a structure for reducing a leakage current.

15. The method of claim 14, wherein the photoelectric conversion region and the floating diffusion region are formed in a semiconductor substrate, and the floating diffusion region includes
a first impurity region formed at a surface portion of the semiconductor substrate;
a second impurity region formed at the surface portion of the semiconductor substrate and adjacent to the first impurity region, the second impurity region being partially overlapped with the first impurity region; and
a third impurity region formed adjacent to the first impurity region and the second impurity region, the first impurity region being surrounded by the third impurity region.

16. A method of operating an image sensor, the method comprising:
converting incident light into electric charges in a photoelectric conversion region during an integration operation; and
collecting overflow charges, the overflow charges being electric charges which exceed a charge storage capacity of the photoelectric conversion region in a floating diffusion region during the integration operation, if the a level of the incident light exceeds a reference level.

17. The method of claim 16, further comprising:
controlling a dynamic range of the image sensor by selectively adjusting a timing of a reset operation, the reset operation resetting the floating diffusion region before collecting the overflow charges.

18. A method of operating an image sensor, the method comprising:
generating a first output signal during a read out operation based on overflow charges collected by a floating diffusion region, the overflow charges being charges which exceeded a charge storage capacity of a photoelectric conversion region during an integration operation;
generating a reference signal during the read out operation, the reference signal representing a voltage level of the floating diffusion region in a reset state;
generating a second output signal during the read out operation based on charges transferred from the photoelectric conversion region to the floating diffusion region during the read out operation; and
generating an image signal based on the first output signal, the second output signal, and the reference signal.

19. The method of claim 18, further comprising:
performing a first reset operation resetting the floating diffusion region before generating the first signal; and
performing a second reset operation resetting the floating diffusion region after generating the first signal and before generating the reference signal.

20. The method of claim 18, wherein the generating the image signal includes:
generating a first sampling signal based on the first output signal and the reference signal;
generating a second sampling signal based on the second output signal and the reference signal; and
generating the image signal based on the first and second sampling signals.
